(19) United States
(12) Patent Application Publication
(10) Pub. No.: US 2025/0193545 A1
(43) Pub. Date: Jun. 12, 2025

(54) IMAGING DEVICE AND PROCESSING CIRCUIT

(71) Applicant: Panasonic Intellectual Property Management Co., Ltd., Osaka (JP)

(72) Inventor: TAKEYOSHI TOKUHARA, Osaka (JP)

(21) Appl. No.: 19/058,410

(22) Filed: Feb. 20, 2025

Related U.S. Application Data
(63) Continuation of application No. PCT/JP2023/025814, filed on Jul. 13, 2023.

(30) Foreign Application Priority Data
Sep. 22, 2022 (JP) 2022-151196

(51) Int. Cl. H04N 25/57; H04N 25/78; H04N 25/79

(52) U.S. Cl. CPC H04N 25/57; H04N 25/78; H04N 25/79

(57) ABSTRACT

An imaging device includes a photoelectric converter that includes counter and pixel electrodes and a photoelectric conversion layer, a voltage supply circuit that supplies a first voltage to the counter electrode, a detection circuit that outputs a signal corresponding to the pixel electrode potential matching incident light, and an image processing circuit that corrects the signal. The photoelectric converter has photoelectric conversion characteristics in which a photocurrent flowing between the counter and pixel electrodes varies linearly with respect to a potential difference between the counter and pixel electrodes when the potential difference is in a first voltage range. The image processing circuit corrects the signal such that the output varies linearly for the incident light, on the basis of a conversion function derived on the basis of the pixel electrode potential with respect to the incident light at the time when the potential difference is within the first voltage range.

### BACKGROUND

### 1. Technical Field

The present disclosure relates to an imaging device and a processing circuit.

### 2. Description of the Related Art

A stacked imaging device has been proposed as an imaging device of a metal oxide semiconductor (MOS) type. In the stacked imaging device, a photoelectric conversion layer is stacked on a surface of a semiconductor substrate. In the stacked imaging device, for each pixel, a charge generated through photoelectric conversion in the photoelectric conversion layer is accumulated as a signal charge in a charge accumulation region, also referred to as a floating diffusion (FD). The accumulated charge is read using a complementary MOS (CMOS) circuit in the semiconductor substrate. In such a stacked imaging device, a charge in the photoelectric conversion layer is moved by an electric field. Therefore, it has been known that the sensitivity of the imaging device is controllable by controlling the state of potentials around the photoelectric conversion layer as disclosed in Japanese Unexamined Patent Application Publication No. 2019-176463 and Japanese Unexamined Patent Application Publication No. 2019-140673, for example.

### SUMMARY

In the imaging device, the sensitivity of which is controllable by controlling the state of potentials around the photoelectric conversion layer, as disclosed in Japanese Unexamined Patent Application Publication No. 2019-176463 and Japanese Unexamined Patent Application Publication No. 2019-140673, the magnitude of a read signal may not vary linearly with respect to the amount of incident light. One non-limiting and exemplary embodiment provides an imaging device, etc., capable of correcting a signal so as to be linear with respect to the amount of incident light by a simple method.

In one general aspect, the techniques disclosed here feature an imaging device including: a photoelectric converter that includes a first electrode, a second electrode, and a photoelectric conversion layer between the first electrode and the second electrode, and that receives light to generate a charge; a voltage supply circuit that supplies a first voltage to the first electrode; a detection circuit that outputs a signal corresponding to a potential of the second electrode corresponding to an amount of light incident on the photoelectric converter; and an image processing circuit that corrects the signal from the detection circuit and outputs the corrected signal, in which the photoelectric converter has photoelectric conversion characteristics in which a photocurrent that flows between the first electrode and the second electrode varies linearly with respect to a potential difference between the first electrode and the second electrode when the potential difference is within a first voltage range, the voltage supply circuit supplies the first voltage to the first electrode such that a voltage range that can be taken by the potential difference in accordance with the amount of light incident on the photoelectric converter includes at least a part of the first voltage range, and the image processing circuit corrects the signal such that an output varies linearly with respect to the amount of light incident on the photoelectric converter, based on a conversion function derived from variations in the potential of the second electrode with respect to the amount of light incident on the photoelectric converter when the potential difference is within the first voltage range.

According to the present disclosure, it is possible to provide an imaging device, etc., capable of correcting a signal so as to be linear with respect to the amount of incident light by a simple method.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating the configuration of an imaging device according to an embodiment;

FIG. 2 illustrates an exemplary circuit configuration of the imaging device according to the embodiment;

FIG. 3 is a sectional view illustrating a schematic sectional structure of a pixel according to the embodiment;

FIG. 4 schematically indicates an example of the photoelectric conversion characteristics of a photoelectric converter according to the embodiment;

FIG. 5 indicates the relationship between the proportion of an output value from a detection circuit to a maximum value of the output value from the detection circuit and the amount of an error between before and after an output conversion, obtained when the imaging device is caused to operate such that a potential difference ΔV between electrodes of the photoelectric converter according to the embodiment is in a linear region; and

FIG. 6 is a flowchart illustrating an example of the flow of a process performed by an image processing circuit according to the embodiment.

### DETAILED DESCRIPTIONS

### Underlying Knowledge Forming Basis of the Present Disclosure

As disclosed in Japanese Unexamined Patent Application Publication No. 2019-176463 and Japanese Unexamined Patent Application Publication No. 2019-140673, when a signal is read with an electric field applied to the stacked photoelectric conversion layer reduced, the linearity of the read signal with respect to the amount of incident light and the accumulation time degrades, while the dynamic range may be increased. That is, the signal output from the pixel does not vary linearly with respect to the amount of incident light and the accumulation time. When the linearly with respect to the amount of incident light degrades, a white balance correction may not be performed accurately, for example. For example, when a gain is applied to a signal from each pixel as a white balance correction, the degradation in the linearity is amplified. In order to address this issue, it is possible to prepare a look-up table (LUT) for conversion into data that are linear with respect to the amount of incident light in advance and correct the signal using the LUT. Since the output from the pixel may vary in accordance with the ambient temperature, however, reference values that are different among temperatures must be prepared and stored in a memory, in order to reduce a correction error, for example. When there are further parameters that may vary the output from the pixel such as individual differences and fluctuations among pixels, it is necessary to select whether to prepare reference values and increase the memory in accordance with the number of the parameters or to deteriorate the accuracy in linearity by tolerating a correction error.

The present disclosure has been made in view of such an issue, and one non-limiting and exemplary embodiment provides an imaging device, etc., capable of correcting a signal so as to be linear with respect to the amount of incident light by a simple method when a signal output from a pixel does not vary linearly with respect to the amount of incident light.

### Overview of the Present Disclosure

As an overview of the present disclosure, examples of the imaging device and the processing circuit according to the present disclosure will be given below.

A first aspect of the present disclosure provides an imaging device including: a photoelectric converter that includes a first electrode, a second electrode, and a photoelectric conversion layer between the first electrode and the second electrode, and that receives light to generate a charge; a voltage supply circuit that supplies a first voltage to the first electrode; a detection circuit that outputs a signal corresponding to a potential of the second electrode corresponding to an amount of light incident on the photoelectric converter; and an image processing circuit that corrects the signal from the detection circuit and outputs the corrected signal, in which the photoelectric converter has photoelectric conversion characteristics in which a photocurrent that flows between the first electrode and the second electrode varies linearly with respect to a potential difference between the first electrode and the second electrode when the potential difference is within a first voltage range, the voltage supply circuit supplies the first voltage to the first electrode such that a voltage range that can be taken by the potential difference in accordance with the amount of light incident on the photoelectric converter includes at least a part of the first voltage range, and the image processing circuit corrects the signal such that an output varies linearly with respect to the amount of light incident on the photoelectric converter, based on a conversion function derived from variations in the potential of the second electrode with respect to the amount of light incident on the photoelectric converter when the potential difference is within the first voltage range.

In this manner, in an imaging device in which a signal from the detection circuit does not vary linearly with respect to the amount of light incident on the photoelectric converter, the image processing circuit corrects the signal using the conversion function such that the output becomes linear with respect to the amount of light incident on the photoelectric converter. In this event, the conversion function is derived using the linearity of a photocurrent for the potential difference between the first electrode and the second electrode, and thus the conversion function is derived easily and the conversion function itself is simple. Accordingly, the imaging device may correct a signal so as to be linear with respect to the amount of incident light by a simple method.

A second aspect of the present disclosure, for example, provides the imaging device according to the first aspect, in which the image processing circuit corrects the signal based on the conversion function represented by formula 1.

$$Y = δ \cdot In ( \frac{y max}{y max - y} ) \qquad ( formula 1 )$$

where y is an input value for the conversion function, Y is an output value from the conversion function, ymax is a maximum value of the input value for the conversion function, and δ is a constant of proportion.

Consequently, the effect of parameters such as temperature variations, individual differences among imaging devices, and fluctuations among pixels in the pixel region is included in the input value y for the conversion function, and the constant of proportion δ may be determined as a unique value. Accordingly, the image processing circuit may make a linear correction easily without being affected by the parameters.

A third aspect of the present disclosure, for example, provides the imaging device according to the second aspect, in which the image processing circuit calculates the δ from formula 2 using the y that is 10% of the ymax or less.

$$δ = y \cdot {\{ In ( \frac{y max}{y max - y} ) \}}^{- 1} \qquad ( formula 2 )$$

Consequently, since the constant of proportion δ may be calculated using the input value y, the constant of proportion δ of the conversion function may be calculated by a simple method. By calculating the constant of proportion δ using formula 2 in advance, it is also possible to calculate the output value Y for the input value y in advance on the basis of formula 1.

A fourth aspect of the present disclosure, for example, provides the imaging device according to any one of the first to third aspects, in which the image processing circuit includes a memory that stores a table including a result of a conversion based on the conversion function, and corrects the signal based on the table.

This reduces the processing load on the image processing circuit.

A fifth aspect of the present disclosure, for example, provides the imaging device according to any one of the first to fourth aspects, further including a semiconductor substrate on which the photoelectric conversion layer is stacked.

Consequently, the photoelectric converter having the photoelectric conversion characteristics described above may be formed easily.

A sixth aspect of the present disclosure, for example, provides the imaging device according to the fifth aspect, further including a substrate including the image processing circuit, in which the semiconductor substrate is stacked on the substrate.

Consequently, the imaging device may be reduced in area.

A seventh aspect of the present disclosure, for example, provides the imaging device according to the fifth aspect, further including a substrate including the image processing circuit, in which the semiconductor substrate and the substrate are electrically connected to each other.

Consequently, the semiconductor substrate may be reduced in area.

An eighth aspect of the present disclosure, for example, provides the imaging device according to any one of the first to seventh aspects, in which the image processing circuit performs at least one of a gain correction or a gamma correction after correcting the signal based on the conversion function.

Consequently, since the signal from the detection circuit has been corrected so as to vary linearly with respect to the amount of incident light on the basis of the conversion function when performing a gain correction and a gamma correction, the gain correction and the gamma correction may be performed accurately.

A ninth aspect of the present disclosure provides a processing circuit that corrects an input signal based on of a conversion function represented by formula 1 and outputs the corrected input signal.

$$Y = δ \cdot In ( \frac{y max}{y max - y} ) \qquad ( formula 1 )$$

where y is an input value for the conversion function, Y is an output value from the conversion function, ymax is a maximum value of the input value for the conversion function, and δ is a constant of proportion.

Consequently, an output from a detection circuit of a photodetector such as the imaging device may be corrected so as to be linear by a simple method.

A tenth aspect of the present disclosure, for example, provides the processing circuit according to the ninth aspect, including a memory that stores a table including a result of a conversion based on the conversion function.

This reduces the processing load on the processing circuit.

An eleventh aspect of the present disclosure, for example, provides the processing circuit according to the ninth or tenth aspect, in which the δ is calculated from formula 2 using the y that is 10% of the ymax or less.

$$δ = y \cdot {\{ In ( \frac{y max}{y max - y} ) \}}^{- 1} \qquad ( formula 2 )$$

Consequently, since the constant of proportion δ may be calculated using the input value y, the constant of proportion δ of the conversion function may be calculated by a simple method.

Embodiments of the present disclosure will be described in detail below with reference to the drawings. Each of the embodiments to be described below indicates a comprehensive or specific example. The numerical values, shapes, materials, constituent elements, arrangement and connection mode of the constituent elements, steps, order of the steps, etc. are exemplary, and are not intended to limit the present disclosure. A variety of aspects to be described herein may be combined with each other unless any contradiction occurs. Of the constituent elements in the following embodiments, constituent elements not set forth in the independent claims are described as optional constituent elements. In the following description, constituent elements having substantially the same function are occasionally denoted by the same reference sign to omit a description thereof. In order to avoid excessive complication of the drawings, some elements are occasionally not illustrated.

The drawings are schematic drawings, and are not necessarily drawn strictly to scale. Thus, the scales of the drawings do not necessarily coincide with each other, for example.

Herein, terms that describe the relationship between elements such as “equal”, terms that describe the shape of elements such as “square” or “circular”, and numerical ranges do not only express their strict meanings, but also mean substantially equivalent ranges that allow a difference of about a few percent, for example.

The terms “above” and “below” as used herein do not refer to an upper direction (vertically above) and a lower direction (vertically below) in absolute space recognition, but are used as terms prescribed by the relative positional relationship based on the stacking order in the stacking configuration. Specifically, the light receiving side of an imaging device is defined as “above”, and the side opposite to the light receiving side is defined as “below”. The terms “above” and “below” are merely used to indicate the arrangement of members relative to each other, and are not intended to limit the posture of an imaging device during use. The terms “above” and “below” are applied not only when two constituent elements are spaced apart from each other with another constituent element interposed between the two constituent elements, but also when two constituent elements are disposed in close contact with each other.

### Embodiment

### Overall Configuration

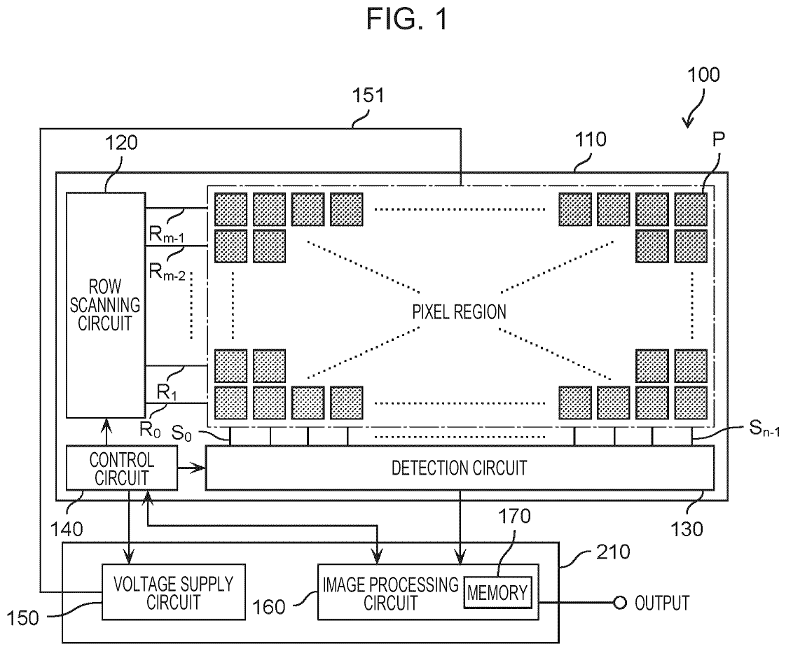

First, the overall configuration of an imaging device 100 will be described with reference to FIG. 1. FIG. 1 is a schematic diagram illustrating the configuration of an imaging device according to an embodiment.

As illustrated in FIG. 1, the imaging device 100 includes a plurality of pixels P each including, as a part thereof, a photoelectric converter supported by a semiconductor substrate 110.

The plurality of pixels P are arranged two-dimensionally, for example, on the semiconductor substrate 110 to form a pixel region. The number and the arrangement of the pixels P are not limited to those in the example illustrated in FIG. 1, and may be determined as desired. For example, the plurality of pixels P may be arranged one-dimensionally so that the imaging device 100 may be used as a line sensor.

As described in detail later with reference to the drawings, the photoelectric converter of each pixel P includes at least a pixel electrode, a translucent counter electrode, and a photoelectric conversion layer interposed between the pixel electrode and the counter electrode. The pixel electrode, the counter electrode, and the photoelectric conversion layer are stacked on the semiconductor substrate 110, for example. The plurality of pixel electrodes are disposed in the pixel region in correspondence with pixels P, for example. On the contrary, the counter electrode is provided in the form of a single electrode layer that is continuous among the plurality of pixels P, for example. That is, a power source that supplies a voltage to the counter electrode and a supply voltage from the power source are common among the plurality of pixels P, for example. A slight difference in potential may be caused among the plurality of pixels P in accordance with the resistance value of the counter electrode and the amount of a flowing current. There may be one or more electrode layers that are continuous among the plurality of pixels P in one imaging device 100. When there is one electrode layer that is continuous among the plurality of pixels P in one imaging device, the voltage to be supplied to the counter electrode for all the pixels P is controllable by one power source. When there are a plurality of electrode layers that are continuous among the plurality of pixels P in one imaging device 100, such as when the electrode layer is divided for rows of the pixels P, for example, different voltages may be supplied to counter electrodes for such rows. The plurality of pixels P may share a single continuous photoelectric conversion layer, as with the counter electrode.

In the configuration illustrated in FIG. 1, the imaging device 100 includes at least a row scanning circuit 120 connected to each pixel P via a row select line R, and a detection circuit 130 connected to each pixel P via an output signal line S. The row scanning circuit 120 and the detection circuit 130 are disposed around the pixel region, for example.

In the example illustrated in FIG. 1, the plurality of pixels P are disposed in a matrix of m rows and n columns. Each of m and n represents an independent natural number. The subscript attached to the reference sign of the row select line R and the output signal line S in FIG. 1 represents the row or the column of the pixels P connected to the row select line R and the output signal line S. The row select line R (R₀ to Rₘ₋₁) is provided for each of the 0-th to (m−1)-th rows of the plurality of pixels P, and electrically connected to one or more pixels P that belong to the same row. Two or more row select lines R may be provided for each row. The output signal line S (S₀ to Sₙ₋₁) is provided for each of the 0-th to (n−1)-th columns of the plurality of pixels P, and electrically connected to output circuits of one or more pixels P that belong to the same column. As illustrated in the drawing, each output signal line S is connected to the detection circuit 130. Two or more output signal lines S may be provided for each column. Although not illustrated in FIG. 1, other wires such as a reset signal line to be described later may be provided for each row or each column, and electrically connected to the pixels P.

The detection circuit 130 may include noise suppression signal processing represented by correlated double sampling, a sample hold circuit, a circuit that performs analog-digital conversion, etc., for example. A pixel signal that expresses an image of a subject is read as an output from the detection circuit 130.

The detection circuit 130 may have a function of detecting the level of an output signal read from the pixels P via the output signal line S. For example, a reference line to which a predetermined voltage is applied during operation is connected to the detection circuit 130. The detection circuit 130 may include one or more comparators that output the result of a comparison between the level of an output signal from the pixels P in each row, that is, the voltage level of each output signal line S, and the voltage level of the reference line, for example. The comparison between the voltage levels may be executed in the form of a comparison between analog voltages, or may be executed in the form of a comparison between digital values. The detection circuit 130 may supply a voltage or a current to the plurality of pixels P via the output signal line S at a timing when signal detection is not performed.

In the configuration illustrated in FIG. 1, the imaging device 100 further includes a control circuit 140, a voltage supply circuit 150, and an image processing circuit 160.

In the configuration illustrated in FIG. 1, the imaging device 100 additionally includes a semiconductor substrate 110 and a substrate 210 that is different from the semiconductor substrate 110. In the example illustrated in FIG. 1, the plurality of pixels P, the row scanning circuit 120, the detection circuit 130, and the control circuit 140 are formed on the semiconductor substrate 110, and the voltage supply circuit 150 and the image processing circuit 160 are formed on the substrate 210. The semiconductor substrate 110 and the substrate 210 are electrically connected to each other. The semiconductor substrate 110 and the substrate 210 are stacked such that the semiconductor substrate 110 is disposed on the upper side, for example. The semiconductor substrate 110 and the substrate 210 are stacked using a substrate pasting technique, for example. In this manner, the semiconductor substrate 110 may be reduced in area by forming the image processing circuit 160 on the substrate 210 which is different from the semiconductor substrate 110 on which the photoelectric conversion layer is stacked. Further, the imaging device 100 may be reduced in area by stacking the semiconductor substrate 110 and the substrate 210.

In the imaging device 100, the positions at which other components are formed are not specifically limited as long as the plurality of pixels P are formed on the semiconductor substrate 110. Each of the row scanning circuit 120, the detection circuit 130, the control circuit 140, the voltage supply circuit 150, and the image processing circuit 160 may be formed on the semiconductor substrate 110, or may be formed on the substrate 210. A part of each of the row scanning circuit 120, the detection circuit 130, the control circuit 140, the voltage supply circuit 150, and the image processing circuit 160 may be formed on the semiconductor substrate 110, and the other part of each of such circuits may be formed on the substrate 210. Alternatively, at least a part of each of the row scanning circuit 120, the detection circuit 130, the control circuit 140, the voltage supply circuit 150, and the image processing circuit 160 may be formed on a substrate, etc., other than the semiconductor substrate 110 and the substrate 210, and the substrate, etc., may be electrically connected to the semiconductor substrate 110 and the substrate 210.

The control circuit 140 receiving instruction data, a clock, etc., provided from the outside of the imaging device 100, and controls the entire imaging device 100, for example. The control circuit 140 may be implemented by a microcontroller that includes one or more processors and a memory, for example.

The control circuit 140 includes a timing generator, and supplies a drive signal to the row scanning circuit 120, the detection circuit 130, the voltage supply circuit 150, etc., for example. In FIG. 1, arrows that extend toward the control circuit 140 and arrows that extend from the control circuit 140 each schematically express an input signal for the control circuit 140 and an output signal from the control circuit 140.

The voltage supply circuit 150 is electrically connected to the pixels P by being connected to a voltage line 151 connected to the counter electrode described above, for example. The voltage supply circuit 150 supplies a predetermined voltage to the photoelectric converter (specifically, the counter electrode) of the pixels P via the voltage line 151 during operation of the imaging device 100.

The voltage supply circuit 150 is able to switchably apply at least two or more different voltages to the voltage line 151, for example. The voltage output from the voltage supply circuit 150 may be changed stepwise, or may be changed continuously. The voltage supply circuit 150 is not limited to a specific power supply circuit, and may be a circuit that converts a voltage supplied from a power source such as a battery to a predetermined voltage or a circuit that outputs one of power supplies from a plurality of systems, or may be a circuit that generates a predetermined voltage. The voltage supply circuit 150 may be a part of the row scanning circuit 120 described above. The voltage supply circuit 150 supplies the voltage line 151 with a voltage in a region in which a photocurrent for a potential difference ΔV between electrodes of the photoelectric converter to be described later varies linearly.

The image processing circuit 160 is electrically connected to the output from the detection circuit 130. The image processing circuit 160 corrects a signal from the detection circuit 130, and outputs the corrected signal. The image processing circuit 160 may be implemented by a digital signal processor (DSP), an image signal processor (ISP), a field-programmable gate array (FPGA), etc., for example. The image processing circuit 160 performs signal processing such as offset addition, offset subtraction, gain correction, white balance correction, noise reduction, Bayer correction, convolution computation, and edge enhancement, for example. The image processing circuit 160 also performs signal processing for linear conversion. Such functions of the image processing circuit 160 may be implemented by a combination of a general-purpose processing circuit and software, or may be implemented by hardware that specializes in such processes.

The image processing circuit 160 includes a memory 170, for example. The memory 170 is a memory capable of storing digital information. The memory 170 stores a conversion table that is used for a linear conversion process to be described in detail later, for example. The conversion table is a table in which a value (input value) before a conversion and a value (output value) after the conversion as the conversion result are correlated, for example. The memory 170 is a non-volatile memory, but may also serve as a volatile memory, for example. Alternatively, the memory 170 may be only a volatile memory, by providing the memory 170 with a function of acquiring and storing data when the power supply for the imaging device 100 is turned on. The memory 170 may be provided in the form of a chip or a package at a location other than the substrate 210. The memory 170 may be shared between the image processing circuit 160 and the control circuit 140.

### Exemplary Configuration of Pixels P

Next, an exemplary configuration of the pixels P of the imaging device 100 will be described.

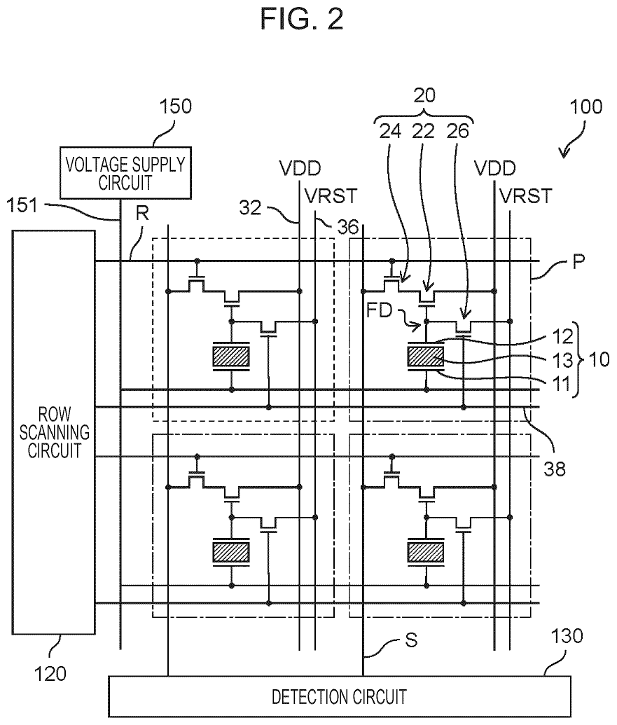

FIG. 2 illustrates an exemplary circuit configuration of the imaging device 100 according to the embodiment. In FIG. 2, four pixels P are extracted from the plurality of pixels P included in the pixel region illustrated in FIG. 1, and schematically illustrated together with the row scanning circuit 120, the detection circuit 130, and the voltage supply circuit 150.

Each of the pixels P includes a photoelectric converter 10 and an output circuit 20 electrically connected to the photoelectric converter 10. The photoelectric converter 10 receives incident light, and generates a signal charge. The output circuit 20 is a circuit that outputs a signal matching the signal charge generated by the photoelectric converter 10. In configuration illustrated in FIG. 2, the output circuit 20 includes a signal detection transistor 22, an address transistor 24, and a reset transistor 26. The signal detection transistor 22, the address transistor 24, and the reset transistor 26 are each a field-effect transistor formed on the semiconductor substrate 110, for example. In the following description, unless otherwise stated, N-channel metal oxide semiconductor field-effect transistors (MOSFETs) are used as the transistors.

As schematically illustrated in FIG. 2, the photoelectric converter 10 includes a counter electrode 11 as an example of a first electrode, a pixel electrode 12 as an example of a second electrode, and a photoelectric conversion layer 13 interposed between the counter electrode 11 and the pixel electrode 12. The counter electrode 11 is translucent. The term “translucent” as used herein means to transmit at least a part of light in a wavelength range that is absorbable by the photoelectric conversion layer 13, and it is not necessary to transmit light in the entire wavelength range of visible light.

The photoelectric conversion layer 13 absorbs light, and generates a signal charge. Specifically, the photoelectric conversion layer 13 receives incident light, and generates a pair of a positive hole and an electron. That is, the signal charge is one of a positive hole and an electron. The signal charge is trapped by the pixel electrode 12, and accumulated in a charge accumulation region including a node FD. When a positive hole is used as the signal charge, for example, the positive hole is trapped by the pixel electrode 12. The electron as a charge that is opposite in polarity to the signal charge is trapped by the counter electrode 11.

As illustrated in the drawing, the counter electrode 11 of each pixel P is electrically connected to the voltage line 151. Thus, the voltage supply circuit 150 is able to collectively apply a voltage to the counter electrodes 11 of the plurality of pixels P via the voltage line 151. In FIG. 2, the voltage line 151 is illustrated as being connected to each of the counter electrodes 11 of the plurality of pixels P. As described above, however, the counter electrode 11 of each pixel P is a single translucent electrode that is continuous among the plurality of pixels P, for example, and it is not necessary that the voltage line 151 should be a wire branched into a plurality of wires.

On the other hand, the pixel electrode 12 is provided electrically separately for each pixel P. As illustrated in the drawing, the pixel electrode 12 of each pixel P is connected to a gate of the signal detection transistor 22 of the corresponding output circuit 20 via the node FD. A source of the signal detection transistor 22 is connected to the corresponding output signal line S via the address transistor 24. A drain of the signal detection transistor 22 is connected to a power supply line 32. The power supply line 32 functions as a source follower power supply when a power supply voltage VDD is applied, for example, during operation. When the power supply line 32 functions as a source follower power supply, the signal detection transistor 22 amplifies and outputs the potential of the node FD. The power supply voltage VDD may be, but is not specifically limited to, about 3.3 V, for example.

The row select line R is connected to a gate of the address transistor 24. The row scanning circuit 120 may retrieve a signal from the pixels P that belong to a selected line to the output signal line S by switching on and off the address transistor 24 by controlling the level of a voltage applied to the row select line R.

In the example illustrated in FIG. 2, the output circuit 20 includes the reset transistor 26. One of a drain and a source of the reset transistor 26 is connected to the node FD. The node FD electrically connects the photoelectric converter 10 to the gate of the signal detection transistor 22. The other of the drain and the source of the reset transistor 26 is connected to a reset voltage line 36. A predetermined reset voltage VRST is applied to the reset voltage line 36 during operation of the imaging device 100. As illustrated in the drawing, a reset signal line 38 is commonly connected to gates of the reset transistors 26 of the plurality of pixels P that belong to the same row, for example.

In the example illustrated in FIG. 2, the reset signal line 38 is connected to the row scanning circuit 120. The row scanning circuit 120 turns on the reset transistors 26 in units of rows of the plurality of pixels P by controlling the level of a voltage applied to the reset signal line 38. Consequently, the potential of the node FD of the pixel P, for which the reset transistor 26 has been turned on, may be reset to VRST.

A potential difference ΔV is generated between the counter electrode 11 and the pixel electrode 12 when a predetermined voltage is applied from the voltage supply circuit 150 to the counter electrode 11 via the voltage line 151 during operation of the imaging device 100. Here, the voltage supply circuit 150 applies, to the counter electrode 11, a voltage that makes the potential of the counter electrode 11 higher than the potential of the pixel electrode 12 with reference to the pixel electrode 12. By making the potential of the counter electrode 11 higher than the potential of the pixel electrode 12, a charge with a positive polarity, for example a positive hole, among positive and negative charges generated in the photoelectric conversion layer 13 by incidence of light, may be collected by the pixel electrode 12 as the signal charge. In the following description, unless otherwise stated, a positive hole is used as the signal charge.

In the present embodiment, a positive hole is used as the signal charge. Therefore, when the voltage applied from the voltage supply circuit 150 to the voltage line 151 at the time of light exposure is defined as V1, V1 makes the potential of the counter electrode 11 higher than the potential of the pixel electrode 12. The initial potential of the pixel electrode 12 at the time of light exposure is determined by the reset voltage VRST described above supplied via the reset transistor 26. That is, the node FD and the pixel electrode 12 are at the same potential, and therefore the potential difference ΔV between the pixel electrode 12 and the counter electrode 11 immediately after resetting is (V1−VRST). In the present embodiment, in which a positive hole is used as the signal charge as described above, a specific value of a voltage that achieves (V1−VRST)>0 during the light exposure period may be selected for V1. Meanwhile, 0 V or a positive voltage around 0 V, for example, is used as the reset voltage VRST.

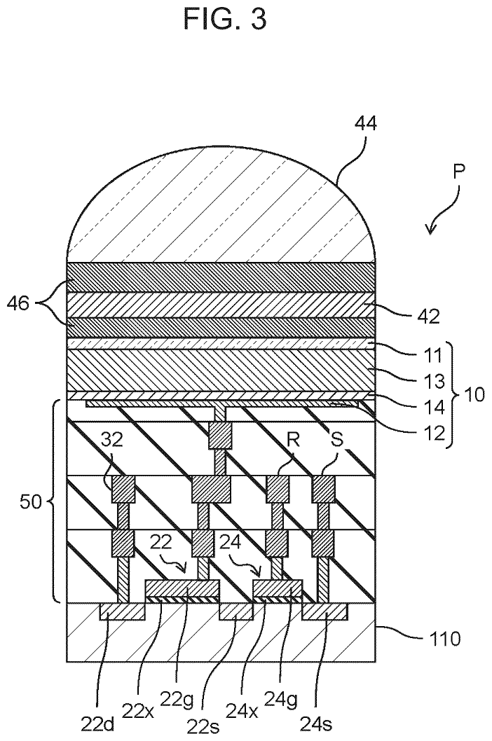

FIG. 3 is a sectional view illustrating a schematic sectional structure of one of the plurality of pixels P according to the present embodiment.

As illustrated in FIG. 3, the counter electrode 11 of the photoelectric converter 10 opposes the pixel electrode 12 via the photoelectric conversion layer 13, and is located above the pixel electrode 12. The counter electrode 11 is located on the side on which light from a subject is incident with respect to the pixel electrode 12 in the imaging device 100, for example. The counter electrode 11 is formed from a transparent conductive material such as indium tin oxide (ITO), for example. As described above, the counter electrode 11 is provided in the form of a single electrode layer that is continuous over the plurality of pixels P, for example. An optical filter 42 such as a color filter, a microlens 44, a sealing film 46, etc., may be stacked and disposed on a principal surface of the counter electrode 11 on the side opposite to the photoelectric conversion layer 13.

The photoelectric conversion layer 13 located between the counter electrode 11 and the pixel electrode 12 is stacked on the semiconductor substrate 110. With such a configuration, the photoelectric converter 10 having the photoelectric conversion characteristics to be described later may be formed easily. The photoelectric conversion layer 13 is formed from an organic material or an inorganic material such as amorphous silicon, for example. The photoelectric conversion layer 13 receives light incident via the counter electrode 11, and generates an exciton, specifically a pair of a positive hole and an electron, through photoelectric conversion. The photoelectric conversion layer 13 may include both a layer constituted from an organic material and a layer constituted from an inorganic material. When an organic material is used for the photoelectric conversion layer 13, the photoelectric conversion layer 13 may be a layer formed by mixing a plurality of materials, that is, a bulk hetero layer. As with the counter electrode 11, the photoelectric conversion layer 13 is provided in the form of a single photoelectric conversion film that is continuous over the plurality of pixels P, for example.

The pixel electrode 12 is located closer to the semiconductor substrate 110 than the photoelectric conversion layer 13, and spatially separated from the pixel electrodes 12 of the other adjacent pixels P to be electrically isolated from such pixel electrodes 12. An inter-layer insulating layer 50, for example, is disposed between the adjacent pixel electrodes 12. The pixel electrode 12 is formed from metal such as aluminum or copper, a metal nitride, or a polysilicon doped with impurities to be rendered conductive, for example.

The photoelectric converter 10 may further include a charge blocking layer 14. The charge blocking layer 14 has a function of passing one of a positive hole and an electron but blocking movement of the other by barrier energy. For the material of the charge blocking layer 14, a material with lower electron affinity than the photoelectric conversion layer 13 is selected when blocking an electron, and a material with higher ionization energy than the photoelectric conversion layer 13 is selected when blocking a positive hole, for example. In the example illustrated in FIG. 3, the charge blocking layer 14 is disposed between the photoelectric conversion layer 13 and the pixel electrode 12. In the present embodiment, the charge blocking layer 14 is an electron blocking layer that has a function of blocking an electron that is opposite in polarity to the signal charge. Although not illustrated, the photoelectric converter 10 may include a positive hole blocking layer that has a function of blocking a positive hole as the signal charge between the photoelectric conversion layer 13 and the counter electrode 11, in addition to or in place of the charge blocking layer 14.

When the photoelectric converter 10 includes the charge blocking layer 14, injection of a charge from the pixel electrode 12 to the photoelectric conversion layer 13 is suppressed, decreasing a dark current. This effect improves the signal detection accuracy of the imaging device 100, in particular the detection accuracy in a region with a small amount of light. While the performance of the imaging device 100 is desirably as high as possible, the imaging device 100 is usable without any problem when a high detection accuracy is not required. When a sufficient energy barrier is formed between the photoelectric conversion layer 13 and the electrode material used, a dark current may be decreased even if the charge blocking layer 14 is omitted. In other words, the charge blocking layer 14 is not necessarily essential in the imaging device 100, and the photoelectric converter 10 may not include the charge blocking layer 14.

A semiconductor substrate containing silicon is used as the semiconductor substrate 110. Here, a P-type silicon (Si) substrate is used as the semiconductor substrate 110. The semiconductor substrate 110 may be an insulated substrate with a semiconductor layer provided on a surface thereof, for example. The semiconductor substrate 110 may include an impurity region and an element separation region. Although not illustrated, the element separation region is provided when electrically separating the output circuits 20 provided for the pixels P between the pixels P, for example. Impurity regions 22d, 22s, and 24s illustrated in FIG. 3 are N-type diffusion regions, for example.

The signal detection transistor 22 includes the impurity regions 22d and 22s, among the impurity regions, a gate insulating layer 22x on the semiconductor substrate 110, and a gate electrode 22g on the gate insulating layer 22x. The impurity region 22d functions as a drain region of the signal detection transistor 22. The impurity region 22s functions as a source region of the signal detection transistor 22. In the illustrated configuration, the address transistor 24 shares the impurity region 22s with the signal detection transistor 22. The address transistor 24 includes a gate insulating layer 24x on the semiconductor substrate 110, a gate electrode 24g on the gate insulating layer 24x, and the impurity regions 22s and 24s. The impurity region 24s functions as a source region of the address transistor 24.

Although not illustrated in FIG. 3, the reset transistor 26 similarly includes impurity regions, a gate insulating layer on the semiconductor substrate 110, and a gate electrode on the gate insulating layer. The reset voltage line 36 described above, for example, is connected to one of the impurity regions.

The power supply line 32 described above is connected to the impurity region 22d as the drain region of the signal detection transistor 22. The output signal line S described above is connected to the impurity region 24s as the source region of the address transistor 24. The row select line R described above is connected to the gate electrode 24g of the address transistor 24.

The inter-layer insulating layer 50 covers the signal detection transistor 22, the address transistor 24, and the reset transistor 26 formed on the semiconductor substrate 110, and other wiring layers and contacts. The photoelectric converter 10 of each pixel P is supported by the inter-layer insulating layer 50. The inter-layer insulating layer 50 includes a plurality of insulating layers each formed from a silicon oxide, a silicon nitride, a polymer membrane, etc., for example.

The node FD includes wires and contacts between the gate electrode 22g and the pixel electrode 12, for example. In addition, as described with reference to FIG. 2, the node FD is connected to the source or the drain of the reset transistor 26. The impurity region that functions as the source or the drain of the reset transistor 26 is of an N-type, and forms a PN junction with a P well in the semiconductor substrate 110. Thus, the impurity region functions as a charge accumulation capacitor that temporarily stores a positive hole as the signal charge. The node FD is floating unless the reset transistor 26 is turned on, and therefore the potential of the node FD and the pixel electrode 12 connected to the node FD rises as the signal charge is accumulated in the node FD.

### Exemplary Photoelectric Conversion Characteristics of Photoelectric Converter 10

Next, the relationship between the photoelectric conversion characteristics of the photoelectric converter 10 and the voltage supplied to the voltage line 151 by the voltage supply circuit 150 will be described. In the following description, unless otherwise stated, a positive hole is used as the signal charge as described above.

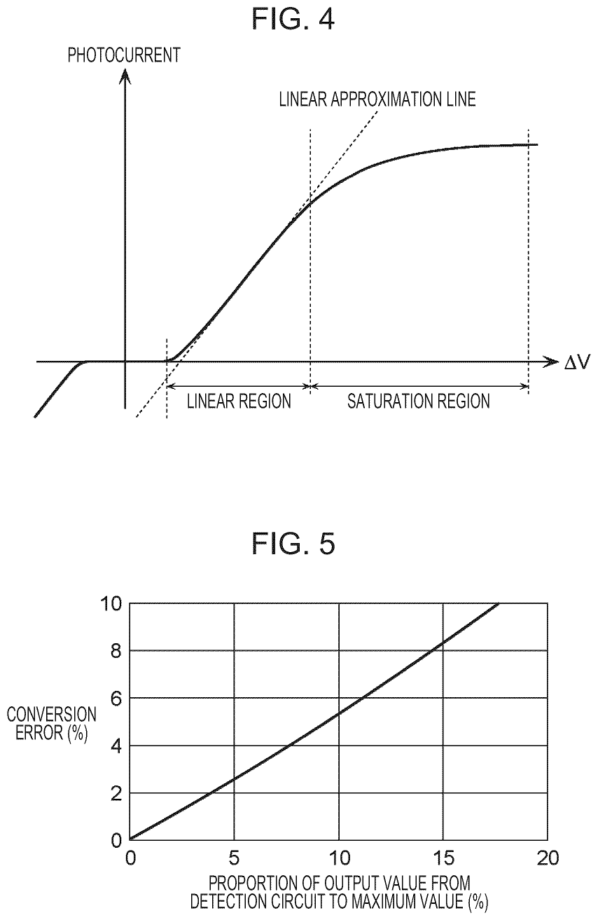

FIG. 4 schematically indicates an example of the photoelectric conversion characteristics of the photoelectric converter 10 according to the present embodiment. FIG. 4 indicates the current-voltage characteristics (I-V characteristics) of the photoelectric converter 10. In FIG. 4, the horizontal axis represents the potential difference ΔV between the counter electrode 11 and the pixel electrode 12. In the present embodiment, the potential difference ΔV is equal to a bias voltage applied between the counter electrode 11 and the pixel electrode 12, for example. ΔV is defined as positive when the potential of the counter electrode 11 is higher than the potential of the pixel electrode 12. In FIG. 4, the vertical axis represents the current that flows to the pixel electrode 12, that is, the current that flows between the counter electrode 11 and the pixel electrode 12, when light is incident on the photoelectric conversion layer 13. Hereinafter, this current will be referred to as a “photocurrent”. When the amount of incident light and the potential difference ΔV are constant, the photocurrent is constant, except for factors for random variations such as shot noise. In other words, when the potential of the counter electrode 11 or the pixel electrode 12 varies and the potential difference ΔV varies, the photocurrent accordingly varies to a matching current value.

In the present embodiment, as indicated in FIG. 4, the photocurrent starts to flow in the photoelectric conversion layer 13 at a certain potential difference ΔV or more. The photocurrent varies so as to increase along an upwardly convex curve with respect to the increase in the potential difference ΔV between the counter electrode 11 and the pixel electrode 12. The photoelectric converter 10 having photoelectric conversion characteristics such as those indicated in FIG. 4 may be implemented using an organic photoelectric conversion material commonly applied to form the photoelectric conversion layer 13 or a combination of the organic photoelectric conversion material and a different material, for example. The photoelectric converter 10 may also be implemented by using an inorganic photoelectric conversion material to form the photoelectric conversion layer 13.

In the example illustrated in FIG. 4, the photocurrent increases in proportion to the potential difference ΔV in a region in which the potential difference ΔV is relatively small, and increases relatively gently with respect to the potential difference ΔV in a region in which the potential difference ΔV is relatively large compared to the above region, with the proportion of increase in the photocurrent decreased as the potential difference ΔV becomes greater. Herein, the voltage range in which the photocurrent increases relatively steeply with respect to the potential difference ΔV between the counter electrode 11 and the pixel electrode 12 is referred to as a “first voltage range” or a “linear region”, and the voltage range in which the photocurrent increases relatively gently with respect to the potential difference ΔV is referred to as a “second voltage range” or a “saturation region”.

In the linear region, the photocurrent that flows between the counter electrode 11 and the pixel electrode 12 varies linearly with respect to the potential difference ΔV, enabling linear approximation. The linear region is a voltage range after a photocurrent rises in the photocurrent characteristics, and in which the photocurrent that flows between the counter electrode 11 and the pixel electrode 12 varies linearly with respect to the potential difference ΔV. The range of the linear region may be determined as a range of the potential difference ΔV in which the amount of deviation of the photoelectric conversion characteristics with respect to the linear approximation line is within 10%, for example. That is, herein, the linear region is a voltage range in which the photocurrent varies substantially linearly with respect to the potential difference ΔV, and may include a voltage range in which the photocurrent characteristics deviate from the linear approximation line. The linear region may be a range of the potential difference ΔV in which the amount of deviation of the photoelectric conversion characteristics with respect to the linear approximation line is 5% or less, or may be a range of the potential difference ΔV in which such an amount of deviation is 3% or less. The linear region is a voltage range in which the photocurrent that flows between the counter electrode 11 and the pixel electrode 12 first varies linearly with respect to the potential difference ΔV when the potential difference ΔV is increased from a potential difference ΔV at which the photocurrent starts to flow, for example. The linear region is a voltage range that includes a potential difference ΔV at which the gradient of the photocurrent with respect to the potential difference ΔV is maximized in the photocurrent characteristics in the example indicated in FIG. 4, for example.

The linear region is a voltage range between the potential difference ΔV at which the photocurrent starts to flow and the saturation region. For example, the linear region is a voltage range in the photocurrent characteristics between an inflection point generated as the potential difference ΔV becomes greater than zero and the photocurrent starts to flow and an inflection point generated as the proportion of increase in the photocurrent decreases as the potential difference ΔV becomes greater. The linear region may be a voltage range from the potential difference ΔV at which the photocurrent starts to flow to a potential difference ΔV in a range in which the linearity of the photocurrent with respect to the potential difference ΔV is kept.

As described above, the linear region according to the present embodiment does not include a minute voltage range in the photocurrent characteristics for the potential difference ΔV, that is, an extremely narrow voltage range in which the linear approximation line is substantially tangent. Thus, the voltage range of the linear region has a range of at least 100 mV or more, and may have a range of 500 mV or more, and may have a range of 1 V or more.

In the saturation region, the flowing photocurrent does not easily increase as the potential difference ΔV becomes greater. In the saturation region, the amount of variations in the photocurrent with respect to the potential difference ΔV is smaller than that in the linear region. Herein, the saturation region is a voltage range in which the photocurrent is substantially saturated, rather than a region including only a voltage range in which the photocurrent is completely saturated and the photocurrent does not increase even if the potential difference ΔV becomes greater. The saturation region is a voltage range in which the potential difference ΔV is greater than that in the linear region.

In the photoelectric conversion characteristics of the photoelectric converter 10, the photocurrent may vary in the negative direction when the potential difference ΔV becomes greater in the negative direction, similarly to the photocurrent on the positive side described above, and there may be a linear region and a saturation region also when an electron is used as the signal charge.

### Operation of Imaging Device 100

Next, operation of the imaging device 100 will be described. Specifically, operation in which the image processing circuit 160 corrects and outputs a signal from the pixel P in the imaging device 100 will be described.

A signal matching the amount of signal charges generated by the photoelectric converter 10 and trapped by the pixel electrode 12 during the light exposure period of the imaging device 100 is output from the output circuit 20 of each pixel P during a reading period. The detection circuit 130 detects the signal output from the output circuit 20, performs noise suppression signal processing, analog-digital conversion, etc., on the detected signal, and outputs the resulting signal to the image processing circuit 160. The detection circuit 130 outputs a signal corresponding to variations in the potential of the pixel electrode 12 matching the amount of light incident on the photoelectric converter 10.

The voltage supply circuit 150 supplies the counter electrode 11 via the voltage line 151 with a voltage V1 that brings the potential difference ΔV between the pixel electrode 12 and the counter electrode 11 into the linear region described above at the time of light exposure. The voltage V1 is an example of a first voltage. Consequently, when light is incident on the photoelectric converter 10, a charge generated through photoelectric conversion is accumulated in the node FD, and the potential of the pixel electrode 12 rises. As a result, in the linear region, the potential difference ΔV becomes smaller and the photocurrent decreases, which makes the node FD less likely to be saturated, effectively increasing the dynamic range. When the amount of charges accumulated in the node FD is small, it may be considered that variations in the potential difference ΔV are small and the photocurrent is constant, that is, the sensitivity is constant. At this time, the signal output from the detection circuit 130 varies linearly. As more and more signal charges are accumulated in the node FD, on the other hand, the amount of the photocurrent decreases, and therefore the signal output from the detection circuit 130 does not vary linearly with respect to the amount of incident light. Therefore, the signal output from the detection circuit 130 is corrected by the image processing circuit 160 as described below.

At the time of light exposure, when the potential of the node FD is defined as VFD, VFD may be represented by the following formula 3.

$$VFD = \frac{1}{CFD} \int I \cdot dt + VRST \qquad ( formula 3 )$$

Here, CFD is the capacity of the node FD, t is the light exposure period, and I is the photocurrent. In addition, VRST is the voltage supplied to the node FD via the reset transistor 26 when resetting the potential of the node FD, and is irrelevant to the signal due to the photoelectric conversion. Thus, hereinafter, it is determined that VRST is equal to 0 for simplicity.

In the linear region, the photocurrent is proportional to the potential difference ΔV=V1−VFD. The constant of proportion is the sensitivity, for example, and the photocurrent is proportional to the amount of incident light. That is, when α is a constant, the photocurrent I is represented by the following formula 4. In formula 4, it is determined that the intercept is 0 for simplicity.

$$I = α ( V 1 - VFD ) \cdot L \qquad ( formula 4 )$$

Here, L is the intensity of light to the photoelectric converter 10. When formula 4 is substituted into formula 3 and the differential equation is solved, the following formula 5 is obtained. Formula 5 is derived on the assumption that the light intensity L is constant during the light exposure period for simplicity.

$$VFD = V 1 \{ 1 - exp ( - \frac{α}{CFD} t \cdot L ) \} \qquad ( formula 5 )$$

The potential VFD represented by the obtained formula 5 is a signal component based on the charge that results from the photoelectric conversion, and the detection circuit 130 detects a signal matching the potential VFD from the output circuit 20 of the pixel P. Accordingly, it is seen that the signal output from the pixel P is not linear with respect to the light intensity L and the light exposure time t when the imaging device 100 is used to operate such that the potential difference ΔV between the pixel electrode 12 and the counter electrode 11 is in the linear region. While the potential VFD rises as a positive hole as the signal charge is accumulated, the potential VFD does not rise any more, even if light is incident on the photoelectric converter 10, when the potential difference ΔV at which the photocurrent becomes 0 is reached. As a result, the signal detected by the detection circuit 130 reaches an upper limit value. Therefore, when the output value from the output circuit 20 of the pixel P is defined as y and the maximum value of the output value is defined as ymax, the output value y from the output circuit may be represented by the following formula 6.

$$y = y max \{ 1 - exp ( - \frac{α}{CFD} t \cdot L ) \} \qquad ( formula 6 )$$

Here, when both sides of formula 6 are represented logarithmically and formula 6 is organized, the following formula 7 is obtained.

$$In ( \frac{y max}{y max - y} ) = \frac{α}{CFD} t \cdot L \qquad ( formula 7 )$$

The output value y from the output circuit 20 and the maximum value ymax of the output value described above may be treated as an output value y of a signal output to the image processing circuit 160 when the detection circuit 130 detects a signal from the output circuit 20 and a maximum value ymax of the output value. The output value y of the signal output from the detection circuit 130 and the maximum value ymax of the output value are digital values after analog-digital conversion, for example. Here, when the left side of formula 7 is defined using the output value Y after the conversion, the output value Y after the conversion is linear with respect to the light exposure time t and the light intensity L, as indicated by the right side. That is, when the original output value y of the signal detected by the detection circuit 130 is converted into the output value Y in accordance with the left side of formula 7, the output after the conversion is linear with respect to the light exposure time t and the light intensity L, even if the imaging device 100 is caused to operate such that the potential difference ΔV between the pixel electrode 12 and the counter electrode 11 is in the linear region. The light exposure time t multiplied by the light intensity L corresponds to the amount of light incident on the photoelectric converter 10, and therefore the output after the conversion varies linearly with respect to the amount of light incident on the photoelectric converter 10. Therefore, in the present embodiment, the image processing circuit 160 performs a process of converting the signal output from the detection circuit 130 on the basis of a conversion function represented by the following formula 8, for example.

$$Y = δ \cdot In ( \frac{y max}{y max - y} ) \qquad ( formula 8 )$$

Here, δ is a constant of proportion. It may also be said that y is an input value for the conversion function, Y is an output value from the conversion function, and ymax is the maximum value of the input value for the conversion function.

While the maximum value ymax of the output value output from the detection circuit 130 is a signal value corresponding to the potential VFD at the time when the node FD is saturated, for example, the maximum value ymax may be replaced with a saturated signal value corresponding to the output bit number of the analog-digital conversion by the detection circuit 130.

The memory 170 may store a conversion table that includes a conversion result based on the conversion function of formula 8. The memory 170 stores a plurality of conversion tables respectively corresponding to the plurality of pixels P, for example. The conversion table is a conversion table in which a conversion result (an output value after the conversion) is correlated with all the output values from the detection circuit 130, for example. In this case, the image processing circuit 160 corrects a signal on the basis of the conversion table. Specifically, the image processing circuit 160 converts an output value input from the detection circuit 130 by collating the output value with values from the table stored in the memory 170. This reduces the processing load on the image processing circuit 160.

By the image processing circuit 160 performing a correction on the basis of the conversion function represented by formula 8, the effect of parameters such as temperature variations, individual differences among imaging devices, and fluctuations among pixels in the pixel region is included in the output value y before the conversion, and therefore the constant of proportion δ may be determined as a unique value. Accordingly, the image processing circuit 160 may make a linear correction easily without considering the effect of the parameters. In the conversion process based on formula 8, in addition, it is not necessary to prepare a table in accordance with the number of parameters such as temperature variations described above, even when value reference with use of an LUT is used, reducing the amount of the memory to be used.

As described above by deriving formula 8, the image processing circuit 160 corrects a signal from the detection circuit 130 such that the output varies linearly with respect to the amount of light incident on the photoelectric converter 10, on the basis of a conversion function derived on the basis of variations in the potential of the pixel electrode 12 with respect to the amount of light incident on the photoelectric converter 10 at the time when the potential difference ΔV is within the linear region. In this manner, even when a signal from the detection circuit 130 does not vary linearly with respect to the amount of light incident on the photoelectric converter 10, the image processing circuit 160 corrects the signal using the conversion function such that the output becomes linear with respect to the amount of light incident on the photoelectric converter 10. In this event, the conversion function is derived using the linearity of the photocurrent with respect to the potential difference ΔV, and thus the conversion function is derived easily and the conversion function itself is simple. Accordingly, it is possible to achieve the imaging device 100 including the image processing circuit 160 capable of correcting a signal so as to be linear with respect to the amount of incident light by a simple method.

The voltage supply circuit 150 supplies the counter electrode 11 via the voltage line 151 with a voltage V1 that brings the potential difference ΔV between the pixel electrode 12 and the counter electrode 11 into the linear region described above at the start of light exposure, for example. The voltage supply circuit 150 may not necessarily apply, to the counter electrode 11, a voltage V1 that brings the potential difference ΔV between the pixel electrode 12 and the counter electrode 11 into the linear region described above at the start of light exposure. That is, the same effect may be achieved by the voltage supply circuit 150 applying, to the counter electrode 11, a voltage V1 that brings the potential difference ΔV between the pixel electrode 12 and the counter electrode 11 into the saturation region described above at the start of light exposure, and varying the potential difference ΔV between the pixel electrode 12 and the counter electrode 11 to be brought into the linear region described above as the signal charge is accumulated in the node FD during light exposure. That is, the voltage supply circuit 150 supplies a voltage V1 to the counter electrode 11 such that the voltage range that may be taken by the potential difference ΔV between the pixel electrode 12 and the counter electrode 11 in accordance with the amount of light incident on the photoelectric converter 10 includes at least a part of the linear region. A user of the imaging device 100 may switch, at a desired timing, the voltage V1 supplied from the voltage supply circuit 150 between a voltage V1 that brings the potential difference ΔV between the pixel electrode 12 and the counter electrode 11 into the linear region and a voltage V2 that brings the potential difference ΔV into the saturation region.

The reason that the output from the output circuit 20 at the time when the imaging device 100 operates such that the potential difference ΔV between the pixel electrode 12 and the counter electrode 11 is within the linear region is not linear with respect to the amount of incident light per light exposure time and unit time, that is, the amount of incident light during the light exposure period, is that the potential of the node FD rises as the signal charge is accumulated and the potential difference ΔV at the photoelectric converter 10 decreases. Thus, when the output value y from the detection circuit 130 is small when the light intensity is low or the light exposure time is short or when both the two conditions are met, the potential difference ΔV at the photoelectric converter 10 hardly varies and the photocurrent decreases slightly. That is, in this case, the output value y may be considered as linear with respect to the amount of incident light. At this time, the output value Y after the conversion may be considered to coincide with the output value y before the conversion. Thus, the constant of proportion δ may be calculated by the following formula 9 in a range in which the output value y from the detection circuit 130 may be considered as linear with respect to the amount of incident light. Formula 9 is derived by deforming formula 8 on the assumption that the output value y from the detection circuit 130 and the output value Y after the conversion coincide with each other.

$$δ = y \cdot {\{ In ( \frac{y max}{y max - y} ) \}}^{- 1} \qquad ( formula 9 )$$

FIG. 5 indicates the relationship between the proportion of the output value y from the detection circuit 130 to the maximum value ymax of the output value from the detection circuit 130 and the amount of an error between before and after the output conversion, obtained when the imaging device 100 is caused to operate such that the potential difference ΔV between the pixel electrode 12 and the counter electrode 11 is in the linear region. In FIG. 5, the horizontal axis represents the proportion (hereinafter also referred to as an “output value proportion”) of the output value y from the detection circuit 130 to the maximum value ymax of the output value from the detection circuit 130. In FIG. 5, the vertical axis represents the proportion (hereinafter also referred to as a “conversion error”) of an error of the output value that results from an output conversion performed using formula 8 to the output value from the detection circuit 130 considered as linear. That is, FIG. 5 indicates how much the output values before and after the conversion based on formula 8 coincide with each other being plotted with respect to the output value proportion for the detection circuit 130.

The range in which the output value y from the detection circuit 130 may be considered as linear with respect to the amount of incident light is determined on the basis of a condition that the conversion error is 10% or less, for example. Specifically, as may be read from FIG. 5, this range is a range in which the output value y from the detection circuit 130 is 17.5% of the maximum value ymax or less. More preferably, the range in which the output value y from the detection circuit 130 may be considered as linear with respect to the amount of incident light may be a range in which the conversion error is 5% or less. In this case, this range is a range in which the output value y from the detection circuit 130 is 9.3% of the maximum value ymax or less.

Therefore, the image processing circuit 160 may calculate the constant of proportion δ from formula 9 using the output value y that is 10% of the maximum value ymax of the output value or less, for example. This allows the constant of proportion δ to be calculated easily. The image processing circuit 160 acquires an output value y of one or more signals output by actually driving the pixel P, and calculates a constant of proportion δ using the acquired output value y, for example. This allows the image processing circuit 160 to calculate the constant of proportion δ using only the output value y output from the detection circuit 130, simplifying the calculation of the constant of proportion δ. When output values y of a plurality of signals are used, constants of proportion δ calculated from the output values y are averaged, for example.

From the viewpoint of suppressing the effect of a reduction in the accuracy of the output value y due to the effect of noise, etc., the output value y that is used to calculate a constant of proportion δ may be 0.5% of the maximum value ymax of the output value or more, or may be 1% of the maximum value ymax of the output value or more.

The image processing circuit 160 stores, in the memory 170, the calculated constant of proportion δ and/or the result of a conversion based on formula 8 in which the calculated constant of proportion δ is used, for example. The image processing circuit 160 corrects a signal from the detection circuit 130 on the basis of formula 8 which uses the constant of proportion δ calculated from formula 9 using the output value y that is 10% of the maximum value ymax of the output value or less, for example.

The constant of proportion δ and the result of a conversion based on formula 8 in which the constant of proportion δ is used, which may be stored in the memory 170, may be updated at any timing. For example, when the power supply for the imaging device 100 is turned on, during operation or in a maintenance mode, one or more output values y may be acquired automatically or manually, a constant of proportion δ may be recalculated on the basis of the acquired output values y and formula 9, and the result of a conversion based on formula 8 may be recalculated using the recalculated constant of proportion δ. The values of a conversion table including the constant of proportion δ and the result of a conversion based on formula 8 in which the constant of proportion δ is used, stored in the memory 170, may be updated to the recalculated constant of proportion δ and conversion result. The method of calculating a constant of proportion δ is not limited to the example described above, and a constant of proportion δ calculated without using formula 9 may be used for the correction by the image processing circuit 160. The memory 170 may store a conversion table including a constant of proportion δ calculated by an external computer, a user, etc., rather than the image processing circuit 160, and the result of a conversion based on formula 8 in which such a constant of proportion δ is used.

The memory 170 has a capacity with a bit number greater than the output bit number of the detection circuit 130 as input data for the image processing circuit 160, for example. For example, when the detection circuit 130 performs analog-digital conversion with 12 bits, the amount of data after the conversion by formula 8 may be 14 bits or more. Further, the amount of data after the conversion may be 20 bits or more, including bits for fractional parts. The memory 170 has a capacity with a bit number to store such data with sufficient accuracy, for example.

Herein, the correction of an output value of a signal from the detection circuit 130 based on a conversion function such as formula 8 described above is also referred to as a “linear conversion process”.

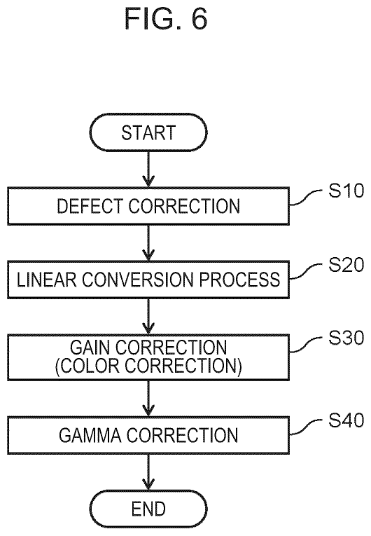

Next, the flow of a process of correcting a signal in the image processing circuit 160 will be described. FIG. 6 is a flowchart illustrating an example of the flow of a process performed by the image processing circuit 160. The image processing circuit 160 corrects a signal output from the detection circuit in accordance with the flow indicated in FIG. 6, for example.

As indicated in FIG. 6, the image processing circuit 160 first performs a defect correction on a signal from the detection circuit 130 (step S10). In the defect correction, a signal from an abnormal pixel P not outputting a signal matching the amount of light incident on the photoelectric converter 10 is compensated for on the basis of signals from pixels P surrounding the abnormal pixel P. For example, an average value of signals from the surrounding pixels P is used as a signal value for the abnormal pixel P. The abnormal pixel P is a pixel P that outputs a value near the upper limit or a value near the lower limit at all times, for example. In the defect correction, signals from pixels P other than the abnormal pixel P are not specifically processed. The image processing circuit 160 may omit the defect correction.

Next, the image processing circuit 160 performs the linear conversion process described above (step S20) on the signal after the defect correction in step S10. In this manner, when the defect correction is performed, the image processing circuit 160 performs the linear conversion process after the defect correction, for example. Consequently, the signal from the pixel P compensated for on the basis of the signals from the surrounding pixels P in the defect correction is also subjected to the linear conversion process. Therefore, when the image processing circuit 160 performs the linear conversion process using the conversion function represented by formula 8, the input value y for the conversion function is the signal value after the defect correction for signals from pixels P subjected to the defect correction, and is the signal value output from the detection circuit 130 for signals from pixels P not subjected to the defect correction.

Next, the image processing circuit 160 performs a gain correction (step S30) and a gamma correction (S40) on the signal subjected to the linear conversion process in step S20. The gain correction is a color correction such as a white balance correction, for example. The gamma correction is a correction for adjustment to the dynamic range for display of an image. In this manner, when the gain correction and the gamma correction are performed, the image processing circuit 160 performs the gain correction and the gamma correction after the linear conversion process. Consequently, since the signal has been corrected so as to be linear with respect to the amount of light incident on the photoelectric converter 10 through the linear conversion process, the gain correction and the gamma correction may be performed accurately on the signal after the linear conversion process. When the imaging device 100 is not provided with a color filter and acquires a monochrome image, for example, the image processing circuit 160 may omit the gain correction in step S30 such as a white balance correction. The user of the imaging device 100 may also switch on and off the gamma correction at a desired timing. In this event, the gamma correction in step S40 may be omitted by switching off the gamma correction. That is, the image processing circuit 160 may not perform at least one of step S30 or step S40.

### Other Embodiments

While the imaging device and the imaging method according to the present disclosure have been described above on the basis of an embodiment, the present disclosure is not limited to such an embodiment.

For example, while a positive hole is used as the signal charge in the above embodiment, the signal charge may be an electron. When an electron is used as the signal charge, the voltage supply circuit 150 applies, to the counter electrode 11, a voltage that makes the potential of the counter electrode 11 lower than the potential of the pixel electrode 12 with reference to the pixel electrode 12. This allows the pixel electrode 12 to trap the electron. Also in this case, the photoelectric converter 10 has photoelectric conversion characteristics in which the photocurrent varies linearly with respect to the potential difference ΔV between the counter electrode 11 and the pixel electrode 12, allowing the image processing circuit 160 to correct a signal in the linear conversion process described above, etc.

While the image processing circuit 160 performs a linear conversion process on the basis of the conversion function represented by formula 8 described above in the above embodiment, for example, this is not limiting. The conversion function that is used for the linear conversion process may be derived by additionally using a parameter that is different from the parameters described above to be represented by a formula other than formula 8.

While the image processing circuit 160 performs a linear conversion process using a conversion table stored in the memory 170 in the above embodiment, for example, this is not limiting. The image processing circuit 160 may perform a linear conversion process through a process in which a conversion table such as a computation process is not used.

The imaging device may not include all the constituent elements described in relation to the above embodiment, and may be composed of only constituent elements that perform objective operation.

A process executed by a specific processor such as the control circuit or the image processing circuit in the above embodiment may be executed by a different processor. The order of a plurality of processes may be changed, or a plurality of processes may be executed concurrently.

A general or specific aspect of the present disclosure may be implemented by a system, a device, a method, an integrated circuit, a computer program, or a computer-readable storage medium such as a compact disc read only memory (CD-ROM). Alternatively, such an aspect of the present disclosure may be implemented by any combination of a system, a device, a method, an integrated circuit, a computer program, and a storage medium.

For example, the present disclosure may be implemented as the imaging device according to the above embodiment, may be implemented as a processing circuit for an imaging device having the function of the image processing circuit according to the above embodiment, may be implemented as a signal processing method for an imaging device performed by the image processing circuit according to the above embodiment, may be implemented as a program causing a computer to execute such a signal processing method, and may be implemented as a non-transitory computer-readable medium storing such a program. In the present disclosure, the image processing circuit according to the above embodiment may be implemented as a processing circuit that is used for a photodetector, etc., other than an imaging device.

Besides, the scope of the present disclosure also includes the embodiment and the example modified variously as contemplated by a person skilled in the art and other forms constructed by combining a part of constituent elements of the embodiment and the example, without departing from the spirit and scope of the present disclosure.

The embodiment of the present disclosure is applicable to photodetection devices, image sensors, etc. For example, the imaging device according to the present disclosure may be used for digital still cameras and digital video cameras such as digital single-lens reflex cameras and digital single-lens mirrorless cameras. Alternatively, the imaging device according to the present disclosure is usable for a variety of camera systems and sensor systems including professional-use cameras for broadcasting purposes, inspection cameras and object recognition cameras for industrial purposes, medical cameras, surveillance cameras, etc., for example. It is also possible to acquire images using infrared light by appropriately selecting the material of the photoelectric conversion layer. Imaging devices that capture images using infrared light may be used for security cameras, in-vehicle cameras, etc., for example. The in-vehicle cameras may be used for input to a control device to allow a vehicle to travel safely, for example. Alternatively, the in-vehicle cameras may be used to assist an operator to allow a vehicle to travel safely.

What is claimed is:

1. An imaging device comprising:
a photoelectric converter that includes a first electrode, a second electrode, and a photoelectric conversion layer between the first electrode and the second electrode, and that receives light to generate a charge;
a voltage supply circuit that supplies a first voltage to the first electrode;
a detection circuit that outputs a signal corresponding to a potential of the second electrode corresponding to an amount of light incident on the photoelectric converter; and
an image processing circuit that corrects the signal from the detection circuit and outputs the corrected signal,
wherein the photoelectric converter has photoelectric conversion characteristics in which a photocurrent that flows between the first electrode and the second electrode varies linearly with respect to a potential difference between the first electrode and the second electrode when the potential difference is within a first voltage range,
the voltage supply circuit supplies the first voltage to the first electrode such that a voltage range that can be taken by the potential difference in accordance with the amount of light incident on the photoelectric converter includes at least a part of the first voltage range, and
the image processing circuit corrects the signal such that an output varies linearly with respect to the amount of light incident on the photoelectric converter, based on a conversion function derived from variations in the potential of the second electrode with respect to the amount of light incident on the photoelectric converter when the potential difference is within the first voltage range.

2. The imaging device according to claim 1,
wherein the image processing circuit corrects the signal based on the conversion function represented by formula 1
$$Y = δ \cdot In ( \frac{y max}{y max - y} ) \qquad ( formula 1 )$$
where y is an input value for the conversion function, Y is an output value from the conversion function, ymax is a maximum value of the input value for the conversion function, and δ is a constant of proportion.

3. The imaging device according to claim 2,
wherein the image processing circuit calculates the δ from formula 2 using the y that is 10% of the ymax or less.
$$δ = y \cdot {\{ In ( \frac{y max}{y max - y} ) \}}^{- 1} \qquad ( formula 2 )$$

4. The imaging device according to claim 1,
wherein the image processing circuit includes a memory that stores a table including a result of a conversion based on the conversion function, and corrects the signal based on the table.

5. The imaging device according to claim 1, further comprising
a semiconductor substrate on which the photoelectric conversion layer is stacked.

6. The imaging device according to claim 5, further comprising
a substrate including the image processing circuit,
wherein the semiconductor substrate is stacked on the substrate.

7. The imaging device according to claim 5, further comprising
a substrate including the image processing circuit,
wherein the semiconductor substrate and the substrate are electrically connected to each other.

8. The imaging device according to claim 1,
wherein the image processing circuit performs at least one of a gain correction or a gamma correction after correcting the signal based on the conversion function.

9. A processing circuit that corrects an input signal based on a conversion function represented by formula 1 and outputs the corrected input signal
$$Y = δ \cdot In ( \frac{y max}{y max - y} ) \qquad ( formula 1 )$$
where y is an input value for the conversion function, Y is an output value from the conversion function, ymax is a maximum value of the input value for the conversion function, and δ is a constant of proportion.

10. The processing circuit according to claim 9, comprising
a memory that stores a table including a result of a conversion based on the conversion function.

11. The processing circuit according to claim 9,
wherein the δ is calculated from formula 2 using the y that is 10% of the ymax or less.
$$δ = y \cdot {\{ In ( \frac{y max}{y max - y} ) \}}^{- 1} \qquad ( formula 2 )$$
